(19) United States
(12) Patent Application Publication
(10) Pub. No.: US 2026/0011589 A1
(43) Pub. Date: Jan. 8, 2026

(54) CASSETTE CARRIER USED IN WET BENCH PROCESS

(71) Applicant: Taiwan Semiconductor Manufacturing Company, Ltd., Hsin-Chu (TW)

(72) Inventors: Ching-Ho HSU, Yunlin County (TW); Feng Hao CHANG, Taichung City (TW); Pei-Hsun TSAI, Hsinchu County (TW); Yun-Yue LIN, Hsinchu City (TW)

(21) Appl. No.: 18/923,999

(22) Filed: Oct. 23, 2024

Related U.S. Application Data
(60) Provisional application No. 63/668,392, filed on Jul. 8, 2024.

(51) Int. Cl. H01L 21/673

(52) U.S. Cl. CPC H01L 21/67383; H01L 21/67359

(57) ABSTRACT

One aspect of the present disclosure pertains to a cassette carrier. The cassette carrier includes a frame defining an interior space having a top opening and a bottom opening, the frame having a first sidewall, a second sidewall, a first connecting wall, and a second connecting wall, where the first and second connecting walls extend between the first sidewall and the second sidewall. The cassette carrier includes a holder disposed across the bottom opening and laterally between the first and the second sidewall, where a through hole is formed in the holder, and an axis through the through hole passes through the top and the bottom openings.

### PRIORITY DATA

This application claims the benefit of U.S. Provisional Application No. 63/668,392, filed Jul. 8, 2024, which is hereby incorporated by reference in its entirety.

### BACKGROUND

In semiconductor processing, semiconductor components such as wafers, photomasks/reticles, pellicles, or other components, may be stored or carried in special containers called cassette carriers (or simply referred to as cassettes, wafer cassettes, or the like). The cassette carrier is a container used to carry and transport such semiconductor components during the manufacturing process of the semiconductor component. In some cases, the semiconductor components, along with the cassette carriers they reside in, are immersed in wet solutions during wet bench processes (e.g., for etching, cleaning, etc.).

However, for sensitive semiconductor components (e.g., extreme ultraviolet (EUV) pellicles), the wet bench processes may cause unstable fluid flow that adversely impacts the semiconductor components sitting in the cassette. Such liquid turbulence may lead to defects on the surface of the semiconductor components such as residues. For example, cassette holders at the base of a cassette carrier may induce turbulent flow, causing defect formation on a semiconductor component such as an EUV pellicle membrane.

Therefore, although existing cassette carrier designs and structures have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a wet bench cassette having cassette holders for supporting a semiconductor component, according to an embodiment of the present disclosure.

FIG. 2 illustrates a semiconductor component to be inserted into the wet bench cassette and supported by the cassette holders, according to an embodiment of the present disclosure.

FIGS. 3A and 3B illustrate a side view and a top view, respectively, of a wet bench cassette without any semiconductor components inserted, according to an embodiment of the present disclosure.

FIGS. 4A and 4B illustrate a side view and a top view, respectively, of a wet bench cassette with a semiconductor component inserted, according to an embodiment of the present disclosure.

FIG. 5 illustrates a perspective view of a wet bench cassette having cassette holders for supporting a semiconductor component, according to an embodiment of the present disclosure.

FIG. 6 illustrates a wet bench cassette submerging into a wet solution, according to an embodiment of the present disclosure.

FIG. 7 illustrates fluid flow around cassette holders causing a turbulence zone in an inserted semiconductor component, according to an embodiment of the present disclosure.

FIG. 8 illustrates a side view of a cassette holder to illustrate further details of the turbulence zone shown in FIG. 7, according to an embodiment of the present disclosure.

FIG. 9 illustrates cassette holders supporting a semiconductor component, according to an embodiment of the present disclosure.

FIGS. 10A-10D illustrate cross-sectional views of a cassette holder cut along the line B-B′ in FIG. 9, according to various embodiments of the present disclosure.

FIG. 11 illustrates fluid flow through a through hole portion of a cassette holder, according to an embodiment of the present disclosure.

FIGS. 12A-12B illustrate various dimensions of a through hole portion of a cassette holder, according to an embodiment of the present disclosure.

FIG. 13 illustrates cassette holders for supporting a semiconductor component, according to another embodiment of the present disclosure.

FIG. 14 illustrates a cross-sectional view of a cassette holder cut along the line B-B′ in FIG. 13, according to various embodiments of the present disclosure.

FIGS. 15A-15D illustrate various configurations of through holes in a cassette holder, according to various embodiments of the present disclosure.

FIGS. 16A-16B illustrate various dimensions of a slanted incline surface of a cassette holder, according to various embodiments of the present disclosure

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to wet bench cassettes used for carrying, holding, and/or transporting semiconductor components during wet bench processes. Specifically, the present disclosure relates to holders at the base of the cassettes for physically supporting the semiconductor components. As described herein, the wet bench processes may include immersing the semiconductor components, along with the cassette carriers they reside in, in wet solutions for cleaning or etching. For sensitive semiconductor components (e.g., extreme ultraviolet (EUV) pellicles, or certain semiconductor wafers), the wet bench processes may cause unstable fluid flow that adversely impacts the semiconductor components sitting in the cassette. Such liquid turbulence may lead to defects on the surface of the semiconductor components such as residues. For example, cassette holders at the base of a cassette carrier may induce turbulent flow, causing defect formation on a semiconductor component such as an EUV pellicle membrane. To address these and related issues, the present disclosure provides cassette holders having structural advantages to prevent dead zones and reduce fluid turbulence. This in turn prevents and reduces defect formation in the semiconductor components during wet bench processes. Some of the structural advantages include the cassette holders having various slanted and vertical surfaces to prevent crisscross of fluid flow, small, rounded contact portion to support the semiconductor components, and through holes that allow liquid to pass through the holder to avoid turbulence.

Embodiments shown in the present disclosure are configured to have EUV pellicles inserted into the wet bench cassettes, but the present disclosure is not limited thereto. Various other semiconductor components (e.g., semiconductor wafers) may be inserted into the wet bench cassettes. The wet bench cassettes described herein may also be referred to as cassettes, cassette carriers, EUV pellicle cassettes, EUV pellicle containers, EUV pellicle carriers, EUV pellicle trays, wafer cassettes, wafer containers, wafer carriers, wafer trays, or the like.

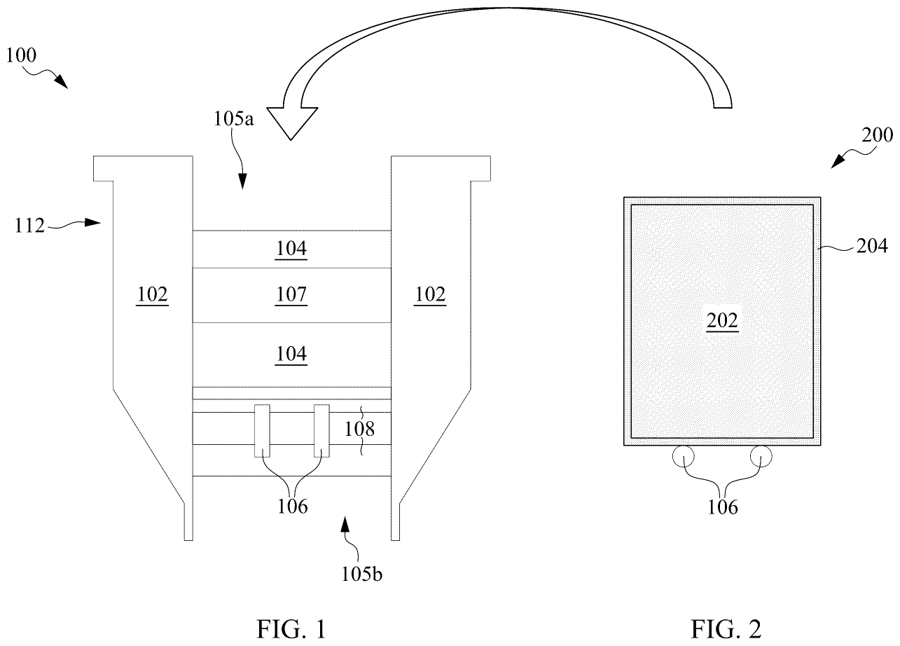

FIG. 1 illustrates a wet bench cassette 100 having cassette holders 106 at its base for carrying and supporting a semiconductor component, according to an embodiment of the present disclosure. FIG. 2 illustrates a semiconductor component, such as an EUV pellicle 200, to be inserted into the wet bench cassette 100 and supported by the cassette holders 106, according to an embodiment of the present disclosure. As shown in FIGS. 1-2, the EUV pellicle 200 may be inserted into the wet bench cassette 100 through a top opening 105a of the wet bench cassette 100. After insertion, the EUV pellicle 200 may physically rest on and be supported by the cassette holders 106 at the base of the wet bench cassette 100.

Referring to FIG. 1, the wet bench cassette 100 may be similar to a Front Opening Unified Pod (FEUP). As shown, the wet bench cassette 100 includes a top opening 105a for inserting the semiconductor components (e.g., EUV pellicles 200), and cassette holders 106 across a bottom opening 105b for supporting the inserted semiconductor components. The wet bench cassette 100 is used in wet processing and has an open structure to allow fluid flow and submersion. In the present embodiment, fluid flows freely through the top and bottom openings 105a and 105b in the vertical direction.

Still referring to FIG. 1, the wet bench cassette 100 has a frame 112 (or shell) that defines an interior space 107 (or cavity) where the semiconductor components are situated. The interior space 107 is vertically between the top and bottom openings 105a and 105b and laterally surrounded by the frame 112. The frame 112 includes sidewalls 102 (or side panels 102) that may have grooves to insert the EUV pellicles 200 into. The EUV pellicles 200 may be square or rectangular sheets. The frame 112 incudes connecting walls 104 (or connecting panes 104) that extend and span between the sidewalls 102. The frame 112 may further include base extensions 108 (as part of or separate from the connecting panes 104). The base extensions 108 extend lengthwise across the bottom of the interior space 107. The cassette holders 106 may be disposed over the base extensions 108, and the cassette holders 106 extend lengthwise perpendicularly to the base extensions 108 across the bottom opening 105b. In some embodiments (like as shown), there are openings in the connecting panes 104 to allow lateral fluid flow (in addition to the vertical fluid flow through the top and bottom openings 105a and 105b). In even further embodiments, there are also openings in the side panels 102 to allow additional lateral fluid flow.

Referring to FIG. 2, the EUV pellicle 200 is an example semiconductor component that is stored and carried around by the wet bench cassette 100, and as noted above, other semiconductor components may also be stored and carried by the wet bench cassette 100. The EUV pellicle 200 includes a pellicle membrane 202 surrounded by a pellicle frame 204 along its perimeter. In the present embodiments, the pellicle frame 204 is a border frame that is adjacent to and laterally disposed on perimeter portions of the pellicle membrane 202. The pellicle membrane 202 may be a thin transparent membrane made of any suitable materials such as carbon-based or graphene-based nanomaterials. The EUV pellicle 200 is used to cover an EUV reticle (also known as an EUV photomask) to protect the EUV reticle from contamination and defects during EUV lithography. However, if defects such as residues occur on the pellicle membrane 202 during wet bench processing, the EUV reticle will adversely affect the EUV processing outcome. For example, a light source entering and exiting the pellicle membrane 202 may run into particle residue that cause reflected EUV light to be inaccurate, causing defects in semiconductor patterns. To address these and other issues, the present disclosure provides specific cassette holders 106 that reduce and prevent residue formation on the pellicle membrane 202 during wet bench processing.

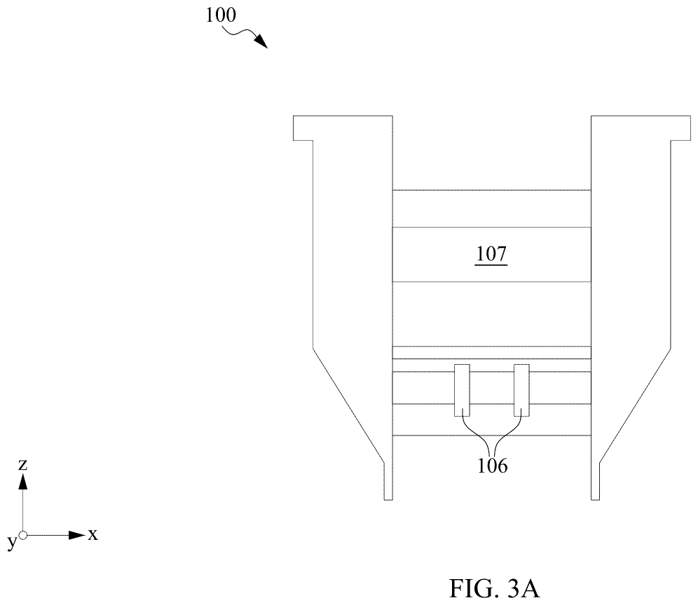

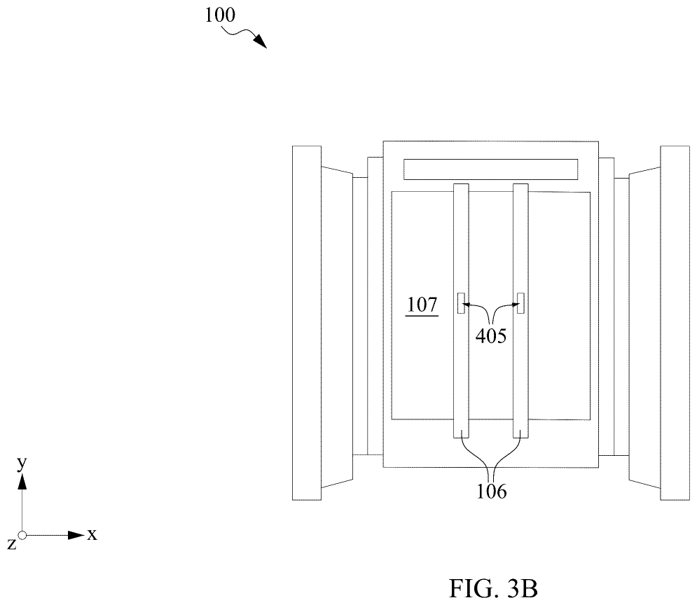

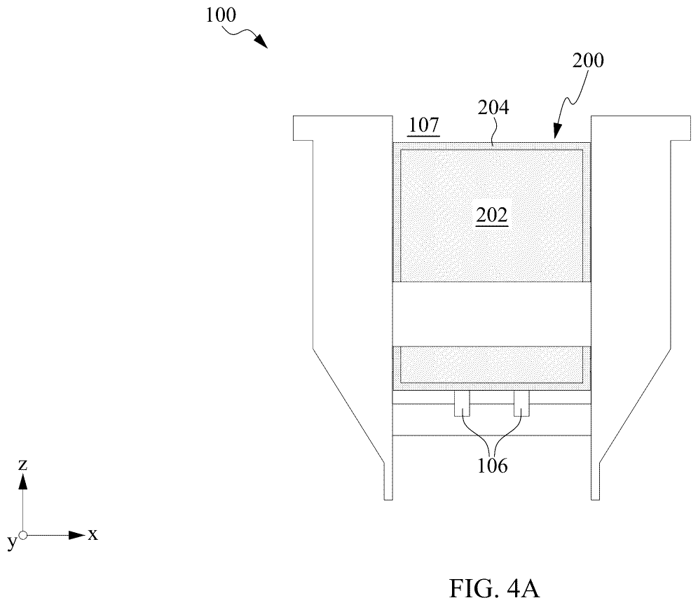

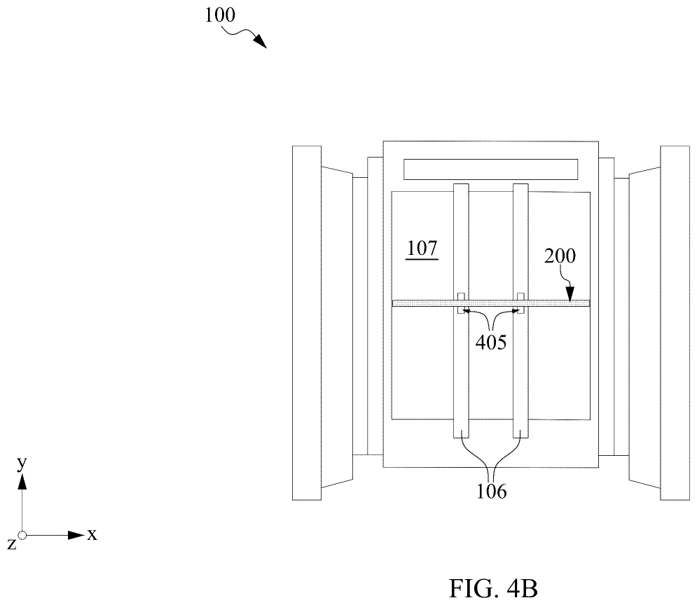

FIGS. 3A and 3B illustrate a side view and a top view, respectively, of a wet bench cassette 100 without any semiconductor components inserted, according to an embodiment of the present disclosure. FIGS. 4A and 4B illustrate a side view and a top view, respectively, of a wet bench cassette 100 with a semiconductor component inserted (e.g., EUV pellicle 200), according to an embodiment of the present disclosure. Note that the wet bench cassette 100 and the EUV pellicle 200 in FIGS. 3A-3B and 4A-4B resemble the wet bench cassette 100 and EUV pellicle 200 described with respect to FIGS. 1-2. As such, certain features are not described or labeled again for the sake of brevity.

Referring to FIGS. 3A-3B and 4A-4B collectively, the wet bench cassette 100 has an interior space 107 and cassette holders 106 at its base for holding EUV pellicles 200. As described herein, the cassette holders 106 provide pellicle support as an example but may also support other semiconductor components such as wafers. As shown from the side and top views, the wet bench cassette 100 has a middle cavity portion (i.e., interior space 107) that allow fluid to flow vertically, and also laterally at least in one direction (e.g., in the y direction, in the x direction, or both, depending on if there are openings in the side panels 102 and/or connecting panes 104). Also as shown, the cassette holders 106 include hollow zone portions having one or more through holes 405 that vertically penetrate through the cassette holders 106 along an axis through the top and bottom openings 105a and 105b. The EUV pellicle 200 (or specially the pellicle frame 204 and/or pellicle membrane 202) may sit on the hollow zone portions of the cassette holders such that fluid can flow through the through holes 405 in the vertical direction. The EUV pellicle 200 is disposed directly above the one or more through holes 405.

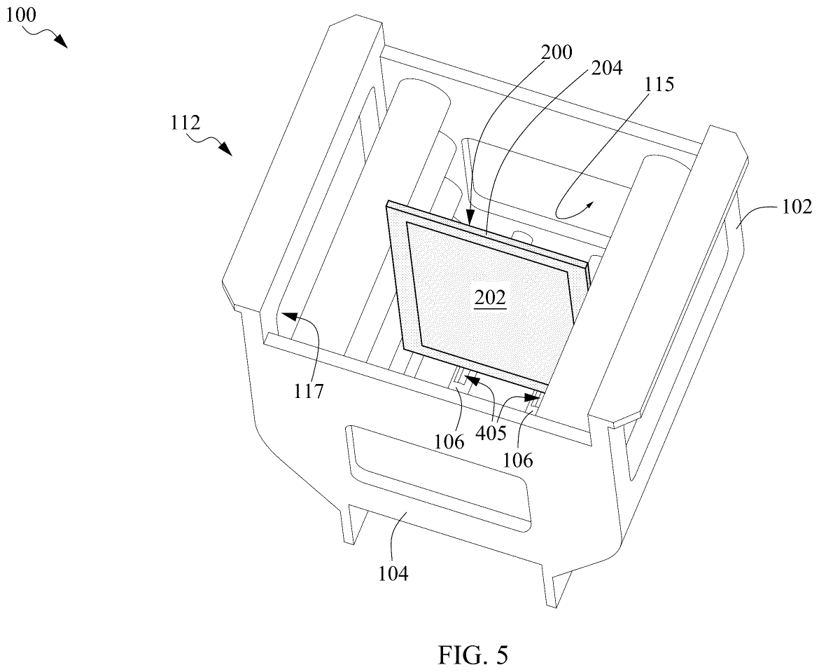

FIG. 5 illustrates a perspective view of a wet bench cassette 100 having cassette holders 106 for supporting a semiconductor component (e.g., EUV pellicle 200), according to an embodiment of the present disclosure. The wet bench cassette 100 of FIG. 5 is consistent with the wet bench cassette 100 described in FIGS. 1-2, 3A-3B, and 4A-4B, and certain features are not described or labeled again for the sake of brevity. As shown, there may be side openings 115 in the connecting panes 104 and side openings 117 in the side panels 102 to allow for lateral fluid flow when the wet bench cassette 100 is dipped and submerged into a wet solution. Note also that the present embodiments illustrate two cassette holders 106 for EUV pellicle support, but more or less cassette holders 106 are possible.

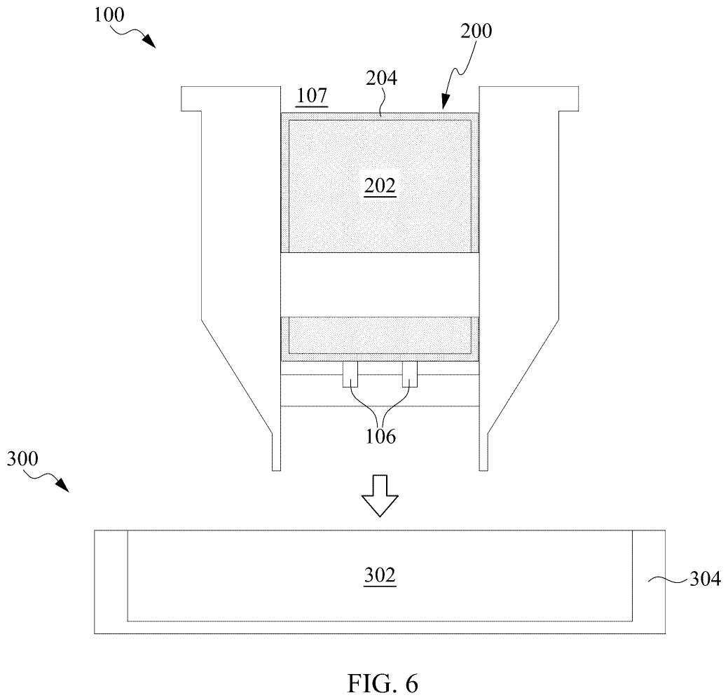

FIG. 6 illustrates a wet bench cassette 100 submerging into a wet solution 302, according to an embodiment of the present disclosure. For example, as part of a wet bench process, the wet bench cassette 100 is dipped into a wet bench tank 300. The wet bench tank 300 includes a container 304 filled with the wet solution 302. The wet solution 302 may include a processing solution for chemical baths, rinses, and/or coatings. The wet solution 302 may be designed for acid or solvent processing. The wet solution may include an etchant (HF+H2O).

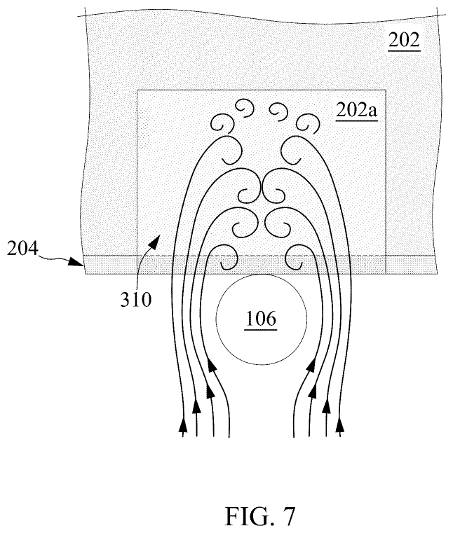

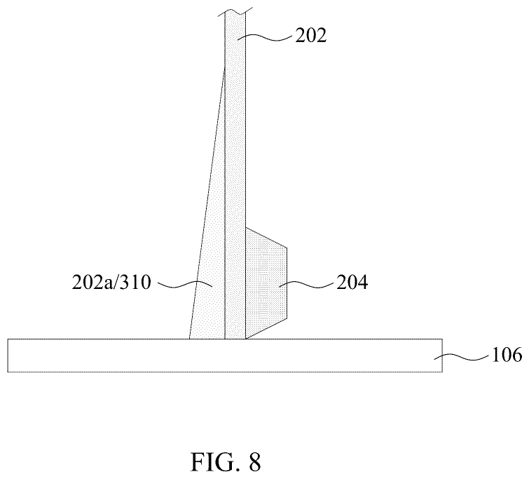

Still referring to FIG. 6, the bottom side of the wet bench cassette 100 is first immersed in the wet solution 302. As such, the cassette holders 106 are usually first immersed before the EUV pellicle 200 (and specifically before the pellicle membrane 202) is immersed. The movement of the wet bench cassette 100 relative to the wet solution 302 will cause fluid flow against the pellicle membrane 202, which may cause fluid flow turbulence leading to defects on the surface of the EUV pellicle membrane 202, as further described in FIGS. 7-8.

FIG. 7 illustrates fluid flow around one or more cassette holders 106, causing a turbulence zone 310 in an inserted semiconductor component (e.g., EUV pellicle membrane 202), according to an embodiment of the present disclosure. When the wet bench cassette 100 is dipped into a wet solution 302, the wet solution 302 may flow upwards as shown. However, where the cassette holders 106 have a cylindrical shape (as shown), the flow may wrap around the curved side surfaces of the holders 106 and crisscross at a top of the holder 106, causing a dead zone and turbulence at a base 202a of the EUV pellicle membrane 202. The base 202a of the EUV pellicle membrane 202 may result in defects and residues on its surface. The areas having such defects may be referred to as the turbulence zone 310. Whereas, as later described, the present disclosure contemplates cassette holders 106 that have an oblique shape with various vertical and slanted surfaces to prevent crisscross flow, a small top contact area for better suspension of the EUV pellicle 200, and a hollow zone with through holes 405 so that fluid can flow through the holders 106 to avoid dead zones and turbulence.

FIG. 8 illustrates a side view of a cassette holder 106 to illustrate further details of the turbulence zone 310 shown in FIG. 7, according to an embodiment of the present disclosure. The side view is cut along a length of the cassette holder 106. As shown, the pellicle membrane 202 and the pellicle frame 204 may both interface a top surface of the cassette holder 106, where the pellicle frame 204 may be laterally attached to the pellicle membrane 202 along perimeters of the pellicle membrane 202. When the wet bench cassette 100 is submerged, due to the fluid flow coming from the bottom of the holder 106, there may be a bigger turbulence zone 310 at the base 202a than towards a top of the EUV pellicle membrane 202. As shown, the turbulence zone decreases in defects/residues from the base 202a of the EUV pellicle membrane 202 to a middle and top (not shown) of the EUV pellicle membrane 202. This is because the defects and the turbulence may be greater towards the base 202a of the pellicle membrane 202 due to the crisscross flow around the cassette holder 106.

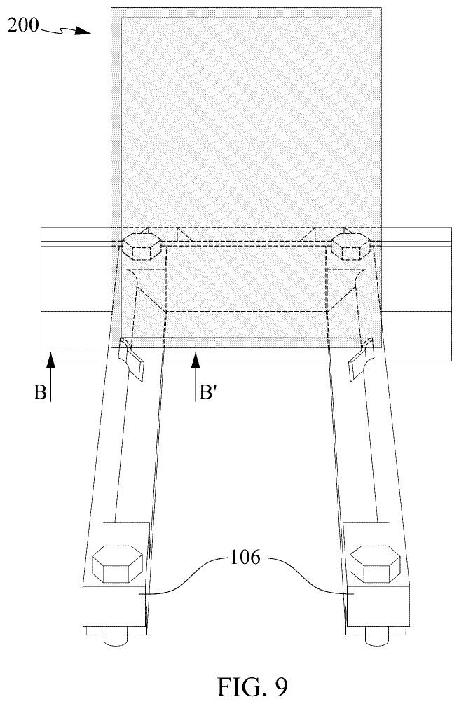

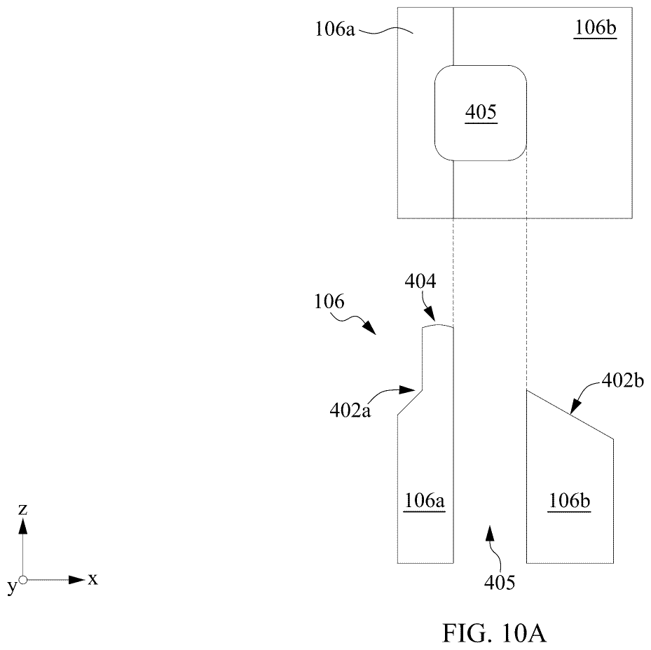

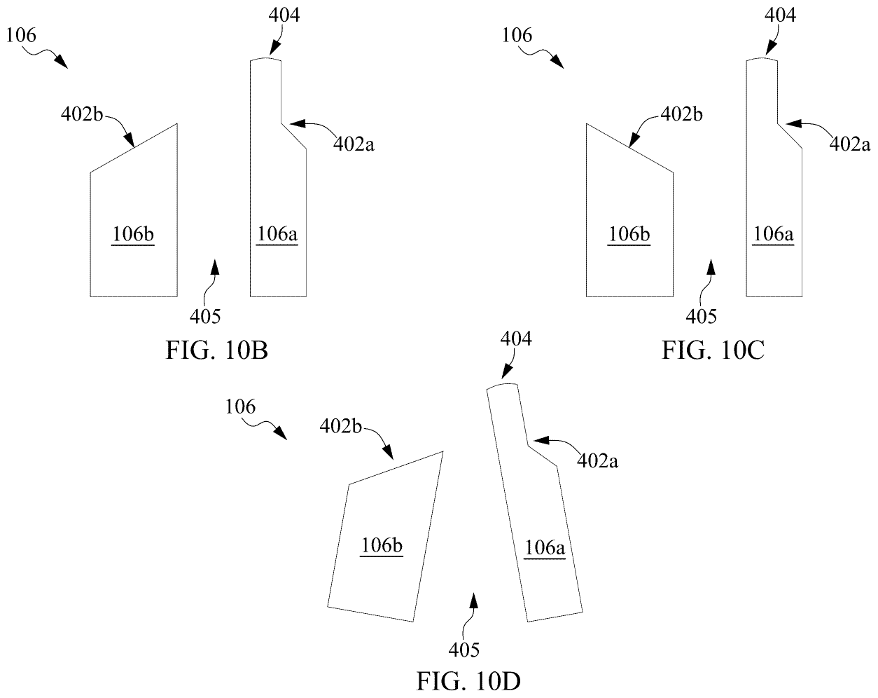

FIG. 9 illustrates cassette holders 106 supporting a semiconductor component (e.g., EUV pellicle 200), according to an embodiment of the present disclosure. FIG. 9 zooms in on the cassette holders 106 of a wet bench cassette 100, such as one previously described. FIG. 9 illustrates a pair of cassette holders 106, and the two holders may be symmetric and mirror each other in shape in the direction that they face each other. The cassette holders 106 may include an acid-and alkali-resistant material such as polytetrafluoroethylene (PTFE). FIGS. 10A-10D illustrate cross-sectional views of the cassette holders 106 cut along the line B-B′ in FIG. 9, according to various embodiments of the present disclosure. The line B-B′ cuts through a hollow zone of one of the cassette holders 106, the hollow zone having a through hole 405 where the EUV pellicle 200 is placed thereover.

Referring to FIG. 10A, each one of the pair of cassette holders 106 includes various oblique surfaces and a through hole 405. The cassette holder 106 includes a contact portion 106a and a noncontact portion 106b. In the hollow zone, the contact portion 106a is separated from the noncontact portions 106b by the through hole 405. The through hole 405 may penetrate through portions of both the contact portion 106a and the noncontact portion 106b. The contact portion 106a is configured to directly contact the EUV pellicle 200, whereas the noncontact portion does not contact the EUV pellicle 200 and merely function to reduce turbulence and direct liquid flow. Each of the contact portion 106a and the noncontact portion 106b are adjacent each other in the x direction and extends lengthwise along the y direction (i.e., a lengthwise direction of the cassette holder 106). Each of the contact portion 106a and the noncontact portion 106b may include vertical (or substantially vertical) side surfaces. These vertical side surfaces may facilitate a more vertical fluid flow to prevent crisscross flow over top surfaces of the holder 106, thereby reducing turbulence in the turbulence zone 310.

The contact portion 106a may include a protruding portion having a rounded top surface 404, and the EUV pellicle 200 lands on the rounded top surface 404. In other words, it is the protruding portion of the contact portion 106a that physically supports and directly contact the EUV pellicle 200. Note that the rounded top surface 404 is the topmost surface of the cassette holder 106. The contact portion 106a may further include a non-protruding portion laterally adjacent the protruding portion in the x direction, the non-protruding portion having an inclined top surface 402a that slopes upwards to interface a vertical side surface of the protruding portion. In the embodiment shown, the protruding portion of the contact portion 106a includes vertical side surfaces on both sides, and one of the vertical side surfaces is a vertical side surface of the contact portion 106a.

In areas not separated by the through hole 405, the noncontact portion 106b may include an inclined top surface 402b that slopes upwards to interface the contact portion 106a, as shown by the combination of the top view and cross-sectional view illustration. In the embodiment shown, the noncontact portion 106b may span a greater width than the contact portion 106a since the contact portion 106a can be minimized for small surface contact area for better suspension of the EUV pellicle 200 (e.g., small rounded top surface 404 and small inclined top surface 402a). Also in the embodiment shown, the through hole 405 penetrates through a bigger portion of the noncontact portion 106b than the contact portion 106a. This is because the noncontact portion 106b is purely configured to reduce turbulence and need not bothered with physically supporting the EUV pellicle 200. In this way, having a majority of the through holes 405 penetrating through the noncontact portion 106b would achieve the noncontact portion's purpose of the of facilitating greater reduction of turbulence.

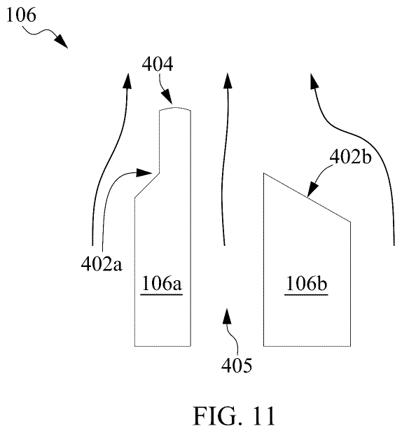

Still referring to FIG. 10A and illustrated in greater detail with respect to FIG. 11, the slanted inclined top surfaces 402a and 402b and the through hole 405 smooths out the liquid flow onto surfaces of the pellicle membrane 202, reducing crisscross flow and turbulence. The unique shape of the cassette holder 106 can provide better structural integrity and cassette holder strength when processing in wet bench. In some examples, a greater than 4% EUV pellicle scrap rate can be reduced by utilizing the cassette holders 106 described herein.

FIGS. 10B-10D resemble FIG. 10A but illustrate additional cassette holder configurations according to further embodiments of the present disclosure. For example, FIG. 10B illustrates the positions of the contact portion 106a and noncontact portion 106b flipped, mirroring the one shown in FIG. 10A; FIG. 10C illustrates the contact portion 106a flipped and mirroring the one shown in FIG. 10B; and FIG. 10D illustrates the shape of the through hole 405 can be changed for non-uniform hole width. Each of these embodiments may produce different flow according to design needs.

FIG. 11 illustrates fluid flow through a hollow zone portion (including a through hole 405) of a cassette holder 106, according to an embodiment of the present disclosure. As shown, due to the oblique surfaces (top inclined surfaces 402a and 402b), rounded end of the contact portion 106a (rounded top surface 404), and the through hole 405; when compared to the fluid flow shown in FIG. 7, there is a more controlled and less disruptive fluid flow around the semiconductor component (e.g., EUV pellicle 200), and the turbulence zone 310 can be reduced or eliminated. For example, the slanted surfaces (top inclined surfaces 402a and 402b) direct fluid flow to avoid crisscross and the through hole 405 allows fluid to escape via an escape path. The combination of oblique slanted surfaces, through hole, and small rounding contact area promotes a more vertical fluid flow, reduces dead zones, and reduces fluid turbulence.

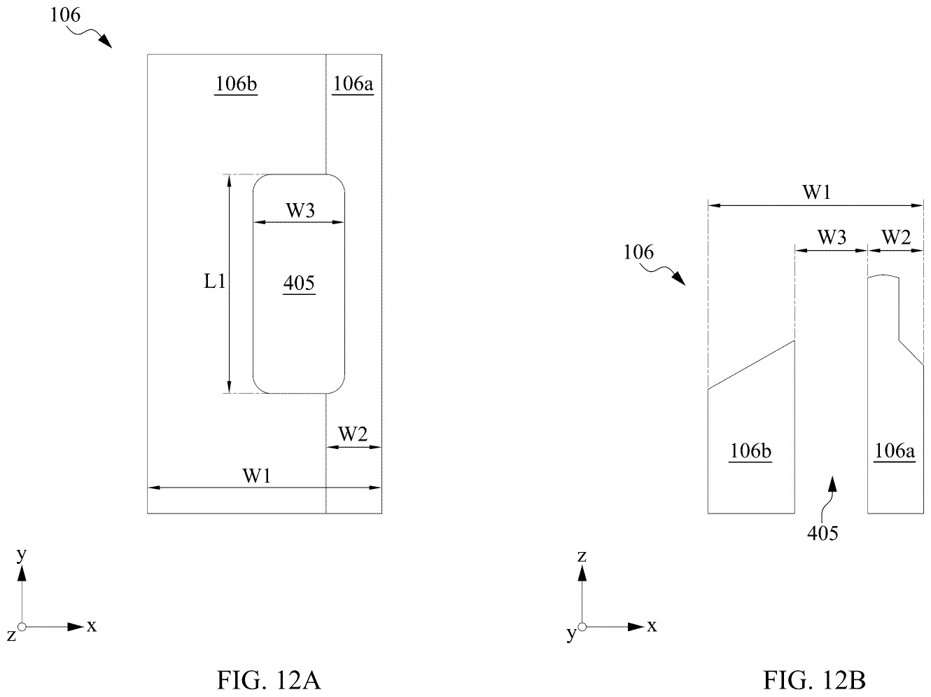

FIGS. 12A-12B illustrate various dimensions of a cassette holder 106, including through hole portions of the cassette holder 106, according to an embodiment of the present disclosure. The through hole portion (also referred to as hollow zone portion) includes one or more through holes 405. Referring to FIGS. 12A and 12B collectively, the cassette holder 106 has a width W1 along the x direction; the contact portion 106a has a width W2 along the x direction, and the through hole 405 has a width W3 along the x direction. In the present embodiment, 0.95W1≥W2≥0.05W1. In other words, the contact portion 106a spans a width W2 greater than 0.05 times the width W1 of the cassette holder 106 but less than 0.95 times the width W1 of the cassette holder 106. If the width W2 spans less than 0.05 times the width W1, the contact portion 106a will not be big enough to physically support the EUV pellicle 200 while facilitating proper liquid flow; but If the width W2 spans greater than 0.95 times the width W1, the contact portion 106a will be too big and not leaving enough structural support for the noncontact portion 106b. In the present embodiment, 0.95W1≥W3≥0.05W1. In other words, the through hole 405 spans a width W3 greater than 0.05 times the width W1 of the cassette holder 106 but less than 0.95 times the width W1 of the cassette holder 106. If the width W3 spans less than 0.05 times the width W1, the through hole 405 will not be big enough to allow adequate liquid escape path for reducing turbulence; but If the width W3 spans greater than 0.95 times the width W1, the through hole will be too big and not leaving enough structural support for the contact portion 106a and the noncontact portion 106b. In the present embodiment, the contact portion 106a has width W2 smaller than a width of the noncontact portion 106b (not labeled) for reasons previously described.

Referring to FIG. 12A, the through hole 405 has a length L1 in the y direction (lengthwise direction of the cassette holders 106). The length L1 should be big enough to get enough smooth flow around the base 202a of the pellicle membrane 202. For example, where the thickness of the EUV pellicle 200 is around 700 μm, the length L1 should be at least greater than 600 μm.

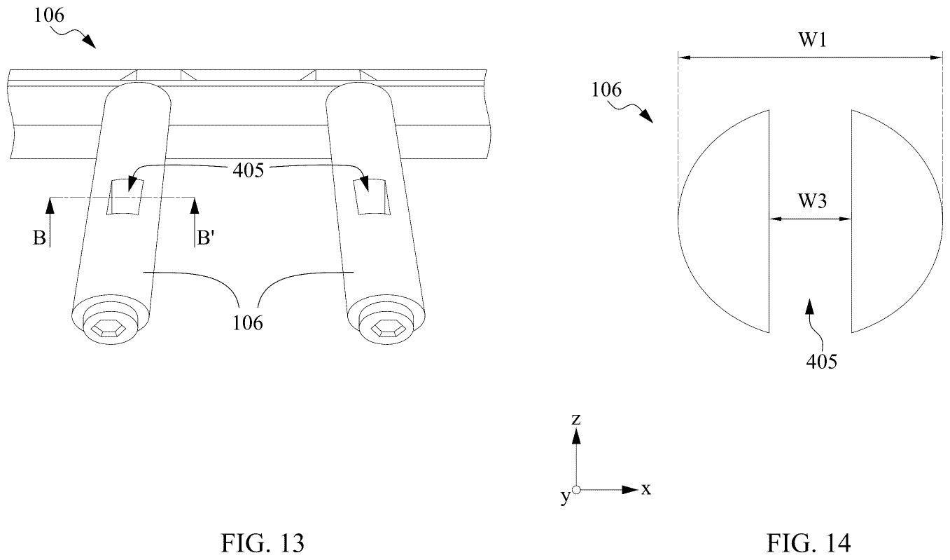

FIG. 13 illustrates cassette holders 106 for supporting a semiconductor component (e.g., EUV pellicle 200), according to another embodiment of the present disclosure. FIG. 14 illustrates a cross-sectional view of a cassette holder 106 cut along the line B-B′ in FIG. 13, according to various embodiments of the present disclosure. Compared to previous embodiments of cassette holder 106, here, the oblique surfaces (e.g., various slanted and vertical surfaces) of the cassette holder 106 is omitted but the through hole 405 remains. For example, the cassette holder 106 has a cylindrical shape that does not distinguish between a contact portion or a noncontact portion, and the cassette holder 106 has a through hole 405 that penetrates through the cylindrical cassette holder 106. In this embodiment, an EUV pellicle 200 may be disposed directly above the through hole 405 and land on top surfaces of the cassette holder 106 on either sides of through hole 405. Like previous embodiments, the cassette holder 106 of FIG. 14 may have a width W1 and its through hole 405 may have a width W3.

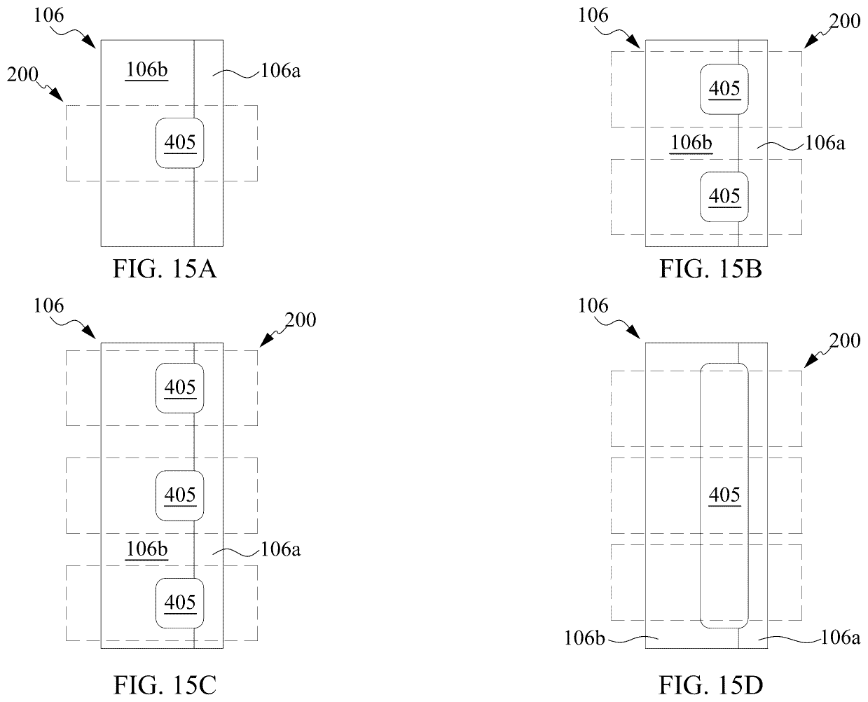

FIGS. 15A-15D illustrate various configurations of through holes 405 in a cassette holder 106, according to various embodiments of the present disclosure. As shown, there can be one or more through holes 405 or a continuous through hole 405 in a cassette holder 106, depending on the number of EUV pellicles 200 that are placed for the wet bench process. In one embodiment (see FIGS. 15A-15C), for every EUV pellicle 200, there is a corresponding through hole 405; and a respective EUV pellicle 200 is placed over each corresponding through hole 405. In another embodiment (see FIG. 15D), there may be one or more continuous through holes 405 where more than one EUV pellicles 200 can be placed thereover.

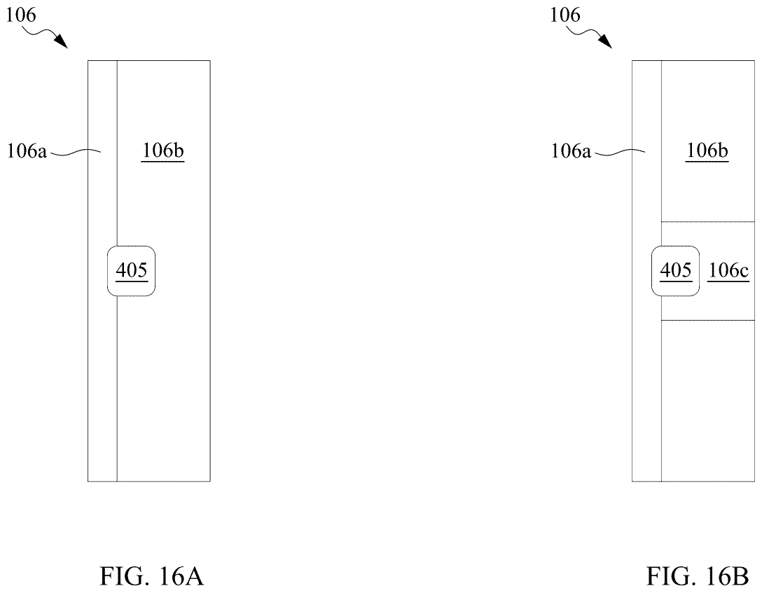

FIGS. 16A-16B illustrate various dimensions of a slanted incline surface (e.g., inclined top surface 402b) of a cassette holder 106, according to various embodiments of the present disclosure. Referring to FIG. 16A, an entirety of the noncontact portion 106b has the inclined top surface 402b previously described. In other words, the inclined top surface 402b spans an entire area of the noncontact portion 106b (not including portions of the through hole 405). Referring to FIG. 16B, the inclined top surface 402b may span only the area 106c of the noncontact portion 106b adjacent to the through hole 405. In other words, the inclined top surface 402b spans an area less than an entire area of the noncontact portion 106b. For example, since the critical portion where there may be turbulence is the area around the through hole 405 (because this is where the EUV pellicle 200 is placed), only this area require the inclined top surface for facilitating smooth liquid flow.

Although not limiting, the present disclosure offers advantages for cassette holders that support semiconductor components (e.g., EUV pellicles) in wet bench processing. One example advantage is that the cassette holders include various oblique surfaces to promote a more streamlined fluid flow, significantly reducing or eliminating turbulence. Another example advantage is that the cassette holders include a rounded end for minimal contact area between the holders and the semiconductor components, thereby minimizing interface and the zone of potential turbulence. Another example advantage is having through holes in the cassette holder to allow for fluid passage, effectively preventing or minimizing the formation of dead zones and allowing fluid passage to reduce turbulence area. Another example advantage is the shape of the cassette holder can provide better structural integrity and cassette holder strength when processing in wet bench.

One aspect of the present disclosure pertains to a cassette carrier. The cassette carrier includes a frame defining an interior space having a top opening and a bottom opening, the frame having a first sidewall, a second sidewall, a first connecting wall, and a second connecting wall, where the first and second connecting walls extend between the first sidewall and the second sidewall. The cassette carrier includes a holder disposed across the bottom opening and laterally between the first and the second sidewall, where a through hole is formed in the holder, and an axis through the through hole passes through the top and the bottom openings.

In an embodiment, the holder has vertical side surfaces. In an embodiment, the holder has one or more slanted top surfaces.

In an embodiment, the holder has a contact portion and a noncontact portion, and the noncontact portion has an inclined top surface that slopes upwards to interface the contact portion, where the contact portion is configured to directly contact a semiconductor component. In a further embodiment, the through hole penetrates through both a portion of the contact portion and a portion of the noncontact portion. In a further embodiment, the contact portion further includes a protruding portion and a non-protruding portion, the protruding portion having a vertical side surface, where the non-protruding portion has an inclined top surface that slopes upwards to interface the vertical side surface of the protruding portion. In a further embodiment, the protruding portion has a rounded top surface configured to directly contact the semiconductor component.

In an embodiment, the cassette carrier further includes a semiconductor component placed on the holder and disposed directly above the through hole. In a further embodiment, the semiconductor component is an extreme ultraviolet (EUV) pellicle having a membrane and a perimeter frame, and the perimeter frame lands on the holder. In another embodiment, the semiconductor component is a semiconductor wafer.

In an embodiment, the holder is a first holder, and the cassette carrier further includes a second holder adjacent the first holder, the second holder also disposed across the bottom opening and laterally between the first and the second sidewall, wherein a second through hole is formed in the second holder, and an axis through the second through hole passes through the top and the bottom openings. In a further embodiment, the cassette carrier further includes a semiconductor component placed on the first and the second holders, and the semiconductor component is disposed directly above the first and the second through holes.

Another aspect of the present disclosure pertains to a holder for supporting a semiconductor component. The holder includes a contact portion extending lengthwise along a first direction, the contact portion has a protruding portion and a non-protruding portion, the protruding portion is adjacent the non-protruding portion in a second direction perpendicular to the first direction, the protruding portion has a rounded top surface configured to physically support the semiconductor component, and the non-protruding portion has an inclined top surface that slopes upwards to interface a vertical side surface of the protruding portion; and a noncontact portion extending lengthwise along the first direction, the noncontact portion is adjacent the contact portion along the second direction, the noncontact portion having an inclined top surface that slopes upwards to interface the contact portion.

In an embodiment, the holder further includes one or more through holes that penetrate vertically through the holder, wherein a portion of the contact portion is separated from a portion of the noncontact portion by the through hole.

In an embodiment, each of the one or more through holes spans a length greater than 600 μm along the first direction.

In an embodiment, along the second direction, each of the one or more through holes spans a width greater than 0.05 times a total width of the holder but less than 0.95 times the total width of the holder.

In an embodiment, along the second direction, the contact portion spans a width greater than 0.05 times a total width of the holder but less than 0.95 times the total width of the holder.

Another aspect of the present disclosure pertains to a cassette carrier. The cassette carrier includes a frame defining an interior space having a top opening and a bottom opening, the frame having a first sidewall, a second sidewall, a first connecting wall, and a second connecting wall, wherein the first and second connecting walls extend between the first sidewall and the second sidewall; and a pair of holders disposed across the bottom opening and laterally between the first and the second sidewall. Each holder in the pair of holders includes a contact portion and a noncontact portion, and the noncontact portion has an inclined top surface that slopes upwards to interface the contact portion, where the contact portion is configured to directly contact a semiconductor component, where one or more through holes are formed through each holder of the pair of holders.

In an embodiment, the inclined top surface spans an entire area of the noncontact portion. In an embodiment, the inclined top surface spans an area less than an entire area of the noncontact portion.

The details of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A cassette carrier, comprising:
a frame defining an interior space having a top opening and a bottom opening, the frame having a first sidewall, a second sidewall, a first connecting wall, and a second connecting wall, wherein the first and second connecting walls extend between the first sidewall and the second sidewall; and
a holder disposed across the bottom opening and laterally between the first and the second sidewall, wherein a through hole is formed in the holder, and an axis through the through hole passes through the top and the bottom openings.

2. The cassette carrier of claim 1, wherein the holder has vertical side surfaces.

3. The cassette carrier of claim 1, wherein the holder has one or more slanted top surfaces.

4. The cassette carrier of claim 1, wherein the holder has a contact portion and a noncontact portion, and the noncontact portion has an inclined top surface that slopes upwards to interface the contact portion, wherein the contact portion is configured to directly contact a semiconductor component.

5. The cassette carrier of claim 4, wherein the contact portion further includes a protruding portion and a non-protruding portion, the protruding portion having a vertical side surface, wherein the non-protruding portion has an inclined top surface that slopes upwards to interface the vertical side surface of the protruding portion.

6. The cassette carrier of claim 5, wherein the protruding portion has a rounded top surface configured to directly contact the semiconductor component.

7. The cassette carrier of claim 4, wherein the through hole penetrates through both a portion of the contact portion and a portion of the noncontact portion.

8. The cassette carrier of claim 1, further comprising a semiconductor component placed on the holder and disposed directly above the through hole.

9. The cassette carrier of claim 8, wherein the semiconductor component is an extreme ultraviolet (EUV) pellicle having a membrane and a perimeter frame, and the perimeter frame lands on the holder.

10. The cassette carrier of claim 8, wherein the semiconductor component is a semiconductor wafer.

11. The cassette carrier of claim 1, wherein the holder is a first holder, further comprising:
a second holder adjacent the first holder, the second holder also disposed across the bottom opening and laterally between the first and the second sidewall, wherein a second through hole is formed in the second holder, and an axis through the second through hole passes through the top and the bottom openings.

12. The cassette carrier of claim 11, further comprising:
a semiconductor component placed on the first and the second holders, and the semiconductor component is disposed directly above the first and the second through holes.

13. A holder for supporting a semiconductor component, the holder comprising:
a contact portion extending lengthwise along a first direction, the contact portion has a protruding portion and a non-protruding portion, the protruding portion is adjacent the non-protruding portion in a second direction perpendicular to the first direction, the protruding portion has a rounded top surface configured to physically support the semiconductor component, and the non-protruding portion has an inclined top surface that slopes upwards to interface a vertical side surface of the protruding portion; and
a noncontact portion extending lengthwise along the first direction, the noncontact portion is adjacent the contact portion along the second direction, the noncontact portion having an inclined top surface that slopes upwards to interface the contact portion.

14. The holder of claim 13, further comprising one or more through holes that penetrate vertically through the holder, wherein a portion of the contact portion is separated from a portion of the noncontact portion by the through hole.

15. The holder of claim 13, wherein each of the one or more through holes spans a length greater than 600 μm along the first direction.

16. The holder of claim 13, wherein along the second direction, each of the one or more through holes spans a width greater than 0.05 times a total width of the holder but less than 0.95 times the total width of the holder.

17. The holder of claim 13, wherein along the second direction, the contact portion spans a width greater than 0.05 times a total width of the holder but less than 0.95 times the total width of the holder.

18. A cassette carrier, comprising:
a frame defining an interior space having a top opening and a bottom opening, the frame having a first sidewall, a second sidewall, a first connecting wall, and a second connecting wall, wherein the first and second connecting walls extend between the first sidewall and the second sidewall; and
a pair of holders disposed across the bottom opening and laterally between the first and the second sidewall,
wherein each holder in the pair of holders includes a contact portion and a noncontact portion, and the noncontact portion has an inclined top surface that slopes upwards to interface the contact portion, wherein the contact portion is configured to directly contact a semiconductor component,
wherein one or more through holes are formed through each holder of the pair of holders.

19. The cassette carrier of claim 18, wherein the inclined top surface spans an entire area of the noncontact portion.

20. The cassette carrier of claim 18, wherein the inclined top surface spans an area less than an entire area of the noncontact portion.
